(19) United States
(12) Patent Application Publication
(10) Pub. No.: US 2002/0175596 A1
(43) Pub. Date: Nov. 28, 2002

(54) Thin profile piezoelectric jet device

(76) Inventors: Suresh V. Garimella, West Lafayette, IN (US); Arvind Raman, Lafayette, IN (US)

Correspondence Address: Mr. Edward J. Timmer, Walnut Woods Centre, 5955 W. Main Street, Kalamazoo, MI, 49009, US

(21) Appl. No.: 09/863,831

(22) Filed: May 23, 2001

(51) Int. Cl. H01L 41/04

(52) U.S. Cl. 310/328; 310/324; 310/330

(57) ABSTRACT

Device for generating one or more cooling air jets comprising a housing having at least one aperture having an axis defining an air flow direction. A piezoelectrically actuated air-moving member is disposed in the housing transverse to the axis of the aperture to move toward and away from the aperture. A source of periodic alternating voltage signals is provided to actuate the piezoelectrically actuated air-moving member in a manner that periodic jets of air are discharged through the one or more apertures in the air flow direction.

### FIELD OF THE INVENTION

The invention relates to a piezoelectric cooling air jet-generating device.

### BACKGROUND OF THE INVENTION

The use of fans for establishing a cooling air circulation in a housing of a portable electronic device is well known in the art. Typically, such fans have comprised piezoelectric fans or rotary type fans. For example, U.S. Pat. No. 5,861,703 describes an axial flow piezoelectric fan wherein a single fan blade is disposed in a housing having an axial flow passage with an inlet an outlet for cooling air. The fan blade carries a piezoelectric element that is electrically actuated to cause the fan blade to vibrate in the housing in a manner that cooling air is drawn in the inlet, flows axially through the air flow passage generally parallel to the housing wall and blade, and is discharged as an axially-flowing air stream from the outlet.

An object of the present invention is to provide a compact, light-weight piezoelectric device as well as method for generating one or more localized cooling air jets that can be directed at a particular electronic component to provide selective cooling thereof.

### SUMMARY OF THE INVENTION

The present invention provides a device and method for generating one or more cooling air jets comprising wherein a housing includes at least one aperture having an axis defining an air flow direction. A piezoelectrically actuated air-moving member is disposed in the housing transverse to the axis of the aperture to move toward and away from the aperture. A source of periodic signals is provided to actuate the piezoelectrically actuated air-moving member in a manner that periodic jets of air are discharged through the aperture in the air flow direction thereof. The frequency of the periodic signals preferably is selected to resonantly drive the air-moving member in the housing. One or more apertures can be provided and preferably have a diameter or major dimension in the range of 1 to 5 millimeters to provide localized, narrow cooling air jets.

In a particular embodiment of the invention, the piezoelectrically actuated air-moving member comprises first and second piezoelectric elements of opposite polarity joined together to form a bimorph piezoelectric member. The first and second piezoelectric elements preferably are bonded together at an interface. Electrodes are connected to outer sides of the bonded piezoelectric elements and the interface is grounded.

In another particular embodiment of the invention, the piezoelectrically actuated air-moving member comprises a blade fixed at one end to the housing and free at an opposite end and a piezoelectric element on the blade.

In still another particular embodiment of the invention, the piezoelectrically actuated air-moving member comprises a blade fixed at opposite ends to the housing and a piezoelectric element on the blade.

Advantages and objects of the invention will become more readily apparent from the following description.

### DESCRIPTION OF THE INVENTION

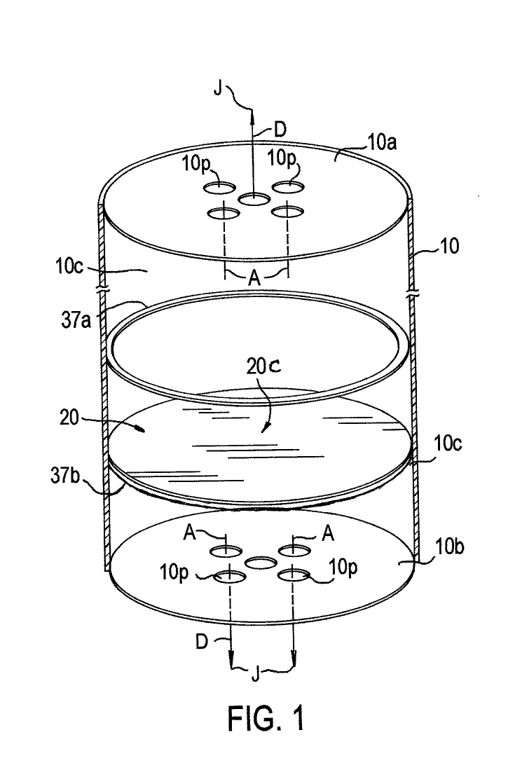

FIG. 1 is an exploded schematic perspective view of a cooling air jet-generating device pursuant to an illustrative embodiment of the invention.

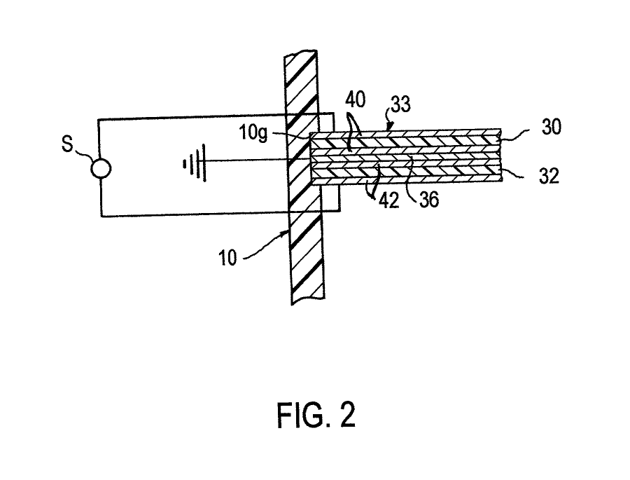

FIG. 2 is a partial enlarged cross-sectional view of the bimorph piezoelectric disc and a groove in the housing wall to receive the peripheral edge of the disc.

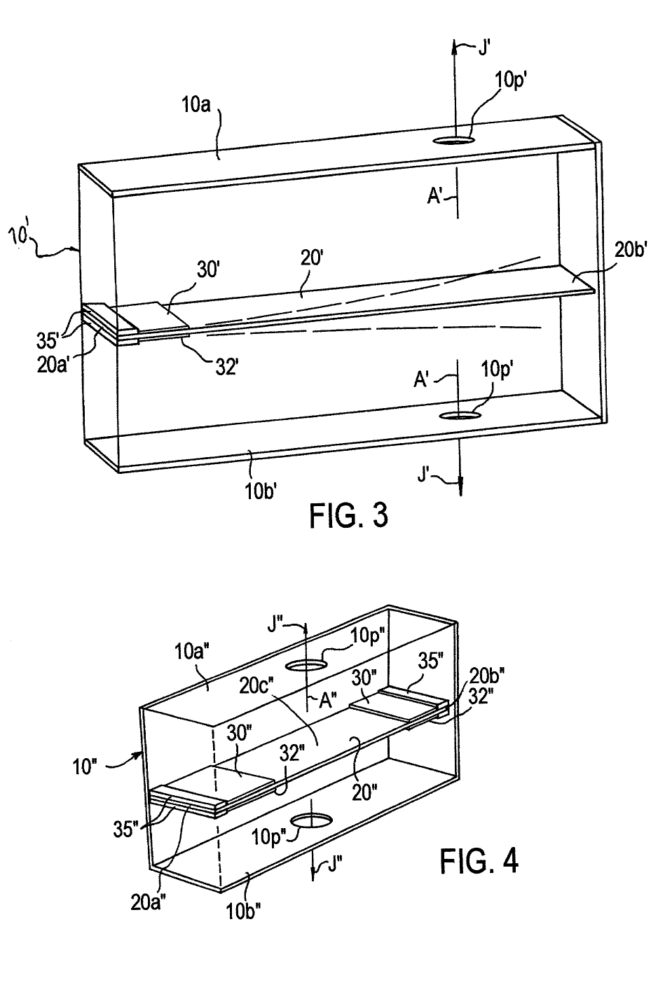

FIG. 3 is a schematic perspective view of a cooling air jet-generating device pursuant to another illustrative embodiment of the invention.

FIG. 4 is a schematic perspective view of a cooling air jet-generating device pursuant to still another illustrative embodiment of the invention.

### DESCRIPTION OF THE INVENTION

The present invention provides a low power, small scale, ultra-light, cooling air piezoelectric jet-generating device to provide one or more localized cooling air jets useful, although not limited, for cooling a particular electronic component, such as an IC chip (integrated circuit chip), in a portable electronic device such as cell phones, laptop computers, personal digital assistance devices and the like. The jet-generating device is advantageous in that it is quiet, generates negligible electromagnetic noise, includes no wearing components and has long life.

Referring to FIGS. 1 and 2, a cooling air-jet generating device pursuant to an illustrative embodiment of the invention is schematically shown as comprising a tubular housing 10 which is shown as cylindrical but may be any suitable shape. The housing 10 includes a first housing closure 10a and a second housing enclosure 10b which can be fastened to opposite open ends of the tubular housing 10 using fasteners, adhesive, welding, and other joining techniques. The housing 10 and closures 10a , 10b can be made of plastic, metal or any suitable material and define a chamber therewithin.

The housing 10 is illustrated as including a plurality (e.g. 5) of apertures 10p on each end closure 10a , 10b . Each aperture 10p has an axis A defining an air flow direction D. The air flow axes A are generally parallel with one another. The apertures 10p can be located at other regions of the housing 10 or end closures.

The apertures 10p are of small size to provide localized cooling air jets J that can be directed at a particular electronic component to be cooled. The apertures 10p are shown as circular in shape but can be of any shape and be present in any number including a single aperture or multiple apertures. The apertures 10p

preferably have a major dimension, such as a diameter or width, in the range of 1 to 5 millimeters to this end.

In FIG. 1, both housing closures 10a , 10b are illustrated as including multiple apertures 10p . However, the invention is not so limited since the invention envisions providing only housing closure 10a or 10b with the apertures 10p. Whether one or both of closures 10a , 10b include apertures will depend upon the particular cooling application to be encountered. For example, apertures 10p can be provided in both housing closures 10a , 10b in the event that first and second electronic components of the portable electronic device require selective cooling by cooling air jets.

A piezoelectrically actuated air-moving member 20 is disposed in the housing 10 and oriented transversely, preferably substantially perpendicularly, to the air flow axes A of the apertures 10p. The air-moving member 20 bifurcates the housing chamber to form upper and lower housing chambers 10c in FIG. 1. The air-moving member 20 comprises first and second piezoelectric elements 30, 32 of opposite polarity joined together by electrically conductive adhesive 36 to form a bimorph piezoelectric member 33. The member 33 is illustrated as comprising a circular disc but any shape can be used depending upon the housing configuration employed. The circumference or peripheral edge of the bimorph member 33 can be received in a circumferential or peripheral groove 10g of the housing, FIG. 2, with its peripheral edge thereby fixed in the housing to permit region 20c to bend. Alternately, or in addition, the circumference or peripheral edge of the bimorph member 33 can be clamped between spacer rings 37a , 37b , FIG. 1, to hold the member 33 in position with its peripheral edge fixed in the housing. The circumference or peripheral edge of bimorph member 33 can be fastened in the groove 10g or to the housing wall by fasteners, adhesive, interference fit and other joining techniques.

The piezoelectric elements 30, 32 can comprise sheets of polyvinylidene fluoride (PVDF) having opposite polarity such that when the bimorph member 33 is subjected to an electric field one element 30 contracts and the other element 32 expands and vice versa depending upon the direction or polarity of the electric field. The sheets are bonded together at an interface formed by conductive adhesive 36 such as comprising silver conductive epoxy adhesive available commercially from MasterBond Inc., Hackensack, N.J. The sheets each typically have a thickness of about 0.7 millimeter, although any other sheet thickness can be used in practice of the invention.

The piezoelectric elements 30, 32 include electrodes 40, 42 in the form of a coating of a metal such as Ni, Ag and the like on each side of each element 30, 32. The electrodes 30, 32 typically overlie the entire outer sides of the piezoelectric elements 30, 32, although the invention is not so limited, and are connected to a conventional electrical power source (drive circuit) S which actuates the piezoelectric elements 30, 32 with a periodic alternating voltage signal at a frequency to drive the movable member 20 at or near resonance. The conductive adhesive 36 is present between the facing electrodes 40, 42 of the elements 30, 32 at the bonded interface and is connected to electrical ground as illustrated to ground the inner electrodes. The elements 30, 32 can be driven at any suitable frequency of oscillation (e.g. from 15 to 100 Hertz) depending upon the magnitude (amplitude) of the periodic alternating voltage signal and vibration characteristics of the bimorph member 33. The periodic alternating voltage signal preferably is tuned to resonantly drive the bimorph member 33 at its first axisymmetric bending frequency to obtain a large amplitude vibration.

To provide an illustrative compact cooling jet-generating device, the opposite sides of bimorph member 33 can be spaced about 1 millimeter from each respective end closure 10a , 10b such that an amplitude of vibration (bending) is less than 1 millimeter. The diameter of the bimorph member 33 can be about 2.54 centimeters. The above dimensions are offered only for purposes of illustration and not limitation as other dimensions can be employed in practice of the invention.

In response to the periodic applied voltage signals, the piezoelectric element 30 contracts and the piezoelectric element 32 expands and vice versa, causing the region 20c of bimorph member 33 to bend up (outward) and down (inward) in FIG. 1 periodically relative to its fixed peripheral edge and create a bending vibration thereof in the housing 10 toward and away from the apertures 10p. These vibrations force the air in the chambers 10c of housing 10 through the associated apertures 10p in the end closures 10a , 10b as cooling air jets J. The air flow is expelled through apertures 10p in the form of time-periodic parallel microjets that impinge on a surface or electronic component to be cooled.

Air is drawn into each chamber 10c during the inward (suction) motion of the bimorph member 33 via the same apertures 10p , although separate air inlet apertures (not shown) can be provided at any location on the housing 10 and its closures 10a , 10b to this end. Separate air inlets can be arranged to draw into the housing 10 warm air from the vicinity of the electronic component being cooled and ejected out of the housing.

The invention also envisions forming the air-moving member 20 by joining (e.g. adhering) the first and second piezoelectric sheet elements 30, 32 on opposite sides of a flexible diaphragm made of Mylar plastic sheet, brass sheet and other bendable material, rather than bonding the elements 30, 32 directly together. The use of such a diaphragm would require that each side of the elements 30, 32 include an electrode for connection to a source S.

Referring to FIG. 3 where like features are represented by like reference numerals primed, another embodiment of the invention is illustrated where a piezoelectrically actuated air-moving member 20′ is shown fixed at one end 20a′ between clamp plates 35′ on the sidewall of the housing 10′ while the opposite end 20b′ is free to move in the housing. The piezoelectrically actuated air-moving member 20′ can comprise a thin Mylar sheet, brass sheet, or other Ad bendable material. Conventional piezoelectric elements 30′, 32′ with metal (e.g. Ni, Ag, etc.) electrodes on their opposite sides as in FIG. 1 are disposed and bonded on opposite sides of the member 20′. The electrodes on the opposite sides of each piezoelectric element are connected to a conventional power source (drive circuit) (not shown) similar to source S providing periodic alternating voltage signals in a manner to impart a periodic bending vibration motion to the air-moving member 20′. The piezoelectric elements may be piezoelectric polymers such as for example polyvinylidene difluoride (PVDF) or piezoceramics such as for example zirconium titanate (PZT). As the voltage to the elements 30′, 32′ alternates, the element 30′ expands and the element 32′ contracts, and vice versa, to impart a periodic bending vibration motion to the air-moving member 20′ in the housing 10′ toward and away from apertures 10p′ as illustrated by dashed lines. The frequency of actuation is tuned to coincide with the natural frequency (fundamental frequency) of the air-moving member 20′ such that large amplitude vibrations result. The invention envisions using only one piezoelectric element 30′ or 32′ on the air-moving member 20′. The vibrations push the air in housing 10′ out of the apertures 10p ′ as time-periodic cooling air microjets J′. Air is drawn into the housing 10′ during the inward (suction) motion of the air-moving member 20′ via the same apertures 10p ′, although separate air inlet apertures (not shown) can be provided at any location on the housing 10′ and its closures 10a′, 10b′, to this end.

Referring to FIG. 4, still another embodiment of the invention is illustrated where a piezoelectrically actuated air-moving member 20″, is shown fixed at both ends 20a″, 20b″ between clamp plates 35″ on opposite sidewalls of the housing 10″. The piezoelectrically actuated air-moving member 20″ can comprise a thin Mylar sheet, brass sheet, or other bendable material. Conventional piezoelectric elements 30″, 32″ with metal (e.g. Ni, Ag, etc.) electrodes on their opposite sides as in FIG. 1 are disposed and bonded and/or fastened on opposite sides of the member 20″ proximate each housing sidewall. The electrodes on the opposite sides of each piezoelectric element 30″, 32″ are connected to a conventional power source (drive circuit) (not shown) similar to source S providing a periodic alternating voltage signals in a manner to impart a periodic bending vibration motion to the air-moving member 20″. As the voltage to the elements 30″, 32″ alternates, a periodic bending vibration motion toward and away from aperture 10p ″ is imparted to the region 20c ″ of the air-moving member 20′ between the fixed ends 20a″, 20b″ in the housing 10g ″. The frequency of actuation is tuned to coincide with the natural frequency (fundamental frequency) of the air-moving member 20″ such that large amplitude vibrations result. The vibrations push the air in housing 10″ out of the apertures 10p ″ as time-periodic cooling air microjets J″. Air is drawn into the housing 10″ during the inward (suction) motion of the air-moving member 20″ via the same apertures 10p ″, although separate air inlet apertures (not shown) can be provided at any location on the housing 10″ and its closures 10a″, 10b ″ to this end. The invention envisions using only one piezoelectric element 30″ or 32″ on a side at each end of the air-moving member 20′.

Although the invention has been described with respect to certain embodiments thereof, those skilled in the art will appreciate that modifications, additions, and the like can be made thereto within the scope of the invention as set forth in the following claims.

We claim

1. A device for generating a jet of air, comprising a housing having an aperture with an axis that defines an air flow direction, and a piezoelectrically actuated air-moving member disposed in said housing to move in a direction toward and away from said aperture in a manner that periodic jets of air are discharged through said aperture in said direction.

2. The device of claim 1 wherein said housing includes an end closure including one or more apertures.

3. The device of claim 1 wherein said piezoelectrically actuated air-moving member comprises first and second piezoelectric elements of opposite polarity joined together to form a bimorph member.

4. The device of claim 3 wherein said first and second piezoelectric elements are bonded together at an interface.

5. The device of claim 4 wherein each said piezoelectric element includes an electrode on an outer side connected to said source and a grounded electrode on an inner side at said interface.

6. The device of claim 3 wherein said bimorph member comprises a circular disc having a region bounded by a peripheral edge, said region being bendable.

7. The device of claim 1 wherein said piezoelectrically actuated air-moving member comprises a blade fixed at one end to said housing and free at an opposite end and a piezoelectric element on said blade.

8. The device of claim 1 wherein said piezoelectrically actuated air-moving member comprises a blade fixed at opposite ends to said housing and a piezoelectric element on said blade.

9. The device of claim 1 including a source of periodic signals for supply to a piezoelectric element of said air-moving member, said signals having a frequency selected to resonantly drive said air-moving member in said housing.

10. The device of claim 1 wherein said aperture has a dimension selected from at least one of a diameter and a width in the range of 1 to 5 millimeters.

11. A device for generating one or more jets of air, comprising a housing having a first aperture at an end and a second aperture at an opposite end, said first aperture and second aperture having substantially parallel axes defining air flow directions, a bimorph member comprising first and second piezoelectric elements of opposite polarity, said bimorph member being disposed in said housing substantially perpendicular to said axes for movement toward and away from said first aperture and second aperture, and a source of periodic signals to actuate said bimorph disc in a manner that periodic jets of air are discharged through said first aperture and second aperture.

12. The device of claim 11 wherein said bimorph member is supported in a groove in said housing.

13. The device of claim 11 wherein said bimorph member comprises a disc.

14. A method of generating a jet of air, comprising moving a piezoelectrically actuated air-moving member disposed in a housing to bend in a direction toward and away from an aperture in the housing to produce periodic jets of air discharged through said aperture in said direction.

15. The method of claim 14 including moving said air-moving member comprising first and second piezoelectric elements of opposite polarity joined together to form a bimorph member.

16. The method of claim 14 including moving said piezoelectrically actuated air-moving member comprising a blade fixed at one end to said housing and free at an opposite end and a piezoelectric element on said blade.

17. The method of claim 14 including moving said piezoelectrically actuated air-moving member comprising a blade fixed at opposite ends to said housing and a piezoelectric element on said blade.

18. The method of claim 14 including resonantly bending said air-moving member.

19. The method of claim 14 including discharging said periodic jets through said aperture having a dimension selected from at least one of a diameter and a width in the range of 1 to 5 millimeters.
